(19) United States
(12) Patent Application Publication
(10) Pub. No.: US 2010/0051964 A1
(43) Pub. Date: Mar. 4, 2010

(54) METHOD FOR PREPARING A SEMICONDUCTOR ULTRANANOCRYSTALLINE DIAMOND FILM AND A SEMICONDUCTOR ULTRANANOCRYSTALLINE DIAMOND FILM PREPARED THEREFROM

(76) Inventors: I-Nan LIN, Taipei City (TW); Nyan-Hwa TAI, Hsinchu (TW)

Correspondence Address: LADAS & PARRY LLP, 224 SOUTH MICHIGAN AVENUE, SUITE 1600, CHICAGO, IL, 60604, US

(21) Appl. No.: 12/391,563

(22) Filed: Feb. 24, 2009

(30) Foreign Application Priority Data
Aug. 28, 2008 (TW) 097132883

(51) Int. Cl. H01L 29/04; H01L 21/04; H01L 29/12

(52) U.S. Cl. 257/77; 438/105; 257/E29.003; 257/E29.068; 257/E21.041

(57) ABSTRACT

A method for preparing a semiconductor ultrananocrystalline diamond (UNCD) film includes doping an UNCD film with an ion source at a dose not less than 10¹⁴ ions/cm² through ion implantation, and annealing the doped UNCD film. A semiconductor UNCD film prepared from the method by using a nitrogen-containing gas as an ion source is also disclosed.

### CROSS-REFERENCE TO RELATED APPLICATION

This application claims priority of Taiwanese application no. 097132883, field on Aug. 28, 2008.

### BACKGROUND OF THE INVENTION

1. Field of the Invention

This invention relates to a method for preparing an ultrananocrystalline diamond (UNCD) film, more particularly to a method for preparing a semiconductor ultrananocrystalline diamond film. The invention further relates to a semiconductor ultrananocrystalline diamond film prepared from the method by using a nitrogen-containing gas as an ion source.

2. Description of the Related Art

Electron sources currently used in field emission techniques are generally formed into a field emitter array (FEA) composed of conical emitters. For example, the conical emitters are made from molybdenum (Mo), have a diameter of about 1 μm, and are set in rows so as to form an array of emitters. However, fabrication of an electron source in the form of a field emission array of conical emitters is a complicated and expensive procedure, regardless of application of this electron source to film-forming, etching, fine-processing, or array-processing uniformity techniques.

UNCD films outperform traditional field emitters made from tungsten (W), molybdenum (Mo) or silicon (Si) material due to their superior electron field emission (EFE) properties, in addition to excellent chemical inertness and mechanical strength. The UNCD films are advanced among the carbon family with 2 to 5 nm sized grains and 0.3 to 0.4 nm wide grain boundaries. Besides, the UNCD films can serve as field emitters in a planar surface form in contrast to the traditional conical emitters. Hence, comparedwith the traditional conical emitters, the UNCD films are potentially suitable for electron sources due to their simplified fabrication procedure and reduced production cost.

It is noted that when an n-type dopant such as nitrogen (N), phosphorus (P), and arsenic (As) is applied to the UNCD film to serve as a substitute for carbon atoms, the n-type dopant can be used as electron donors since it has more valence electrons than the carbon atom. Particularly, for making the UNCD film into a relatively excellent electron source, nitrogen is deemed to be a desirable n-type dopant since it can share valence electrons with carbon through sp³ and sp² hybrid orbitals of σ-bonds or π-bonds.

S. Bhattacharyya et al. in “Synthesis and characterization of highly-conducting nitrogen-doped ultrananocrystalline diamond films,” Applied physics letters, vol. 79, no. 10, Sep. 3, 2001, pp. 1441-1443, discloses a method for doping an UNCD film with nitrogen through microwave plasma enhanced chemical vapor deposition (MPECVD) techniques. Particularly, the doping of the UNCD film with nitrogen is carried out by adding 1 to 20% of N₂ gas to the CH₄ (1%)/Ar plasma while forming the UNCD film.

FIG. 1 shows secondary ion mass spectroscopy (SIMS) data for illustrating a relation curve of the percentage of N₂ gas added to the plasma to the total nitrogen content in the nitrogen (N)-doped UNCD film made by PECVD. The data shown in FIG. 1 indicate that the nitrogen content in the N-doped UNCD film initially increases with the increase of the percentage of N₂ in the plasma but then tends to saturate at about 2×10²⁰ atoms/cm³ when the percentage of N₂ gas in the plasma reaches 5%. The nitrogen content in the N-doped UNCD film hardly increases any further as the percentage of N₂ added to the plasma is raised to more than 5%. Hence, the nitrogen content in the N-doped UNCD film made by PECVD techniques is restricted. Besides, fabrication of the UNCD film through PECVD techniques is disadvantageous to control and quantification of the percentage of N₂ gas in the plasma, and thus, the nitrogen content in the N-doped UNCD film cannot be effectively controlled and raised.

Therefore, there is still a need in the art to provide a simple and economical method for preparing a doped UNCD film, wherein the dopant concentration in the UNCD film can be relatively precisely controlled and wherein the doped UNCD film has improved electron field emission (EFE) properties.

### SUMMARY OF THE INVENTION

Therefore, the object of the present invention is to provide a method for preparing a semiconductor UNCD film and a semiconductor UNCD film thus formed that can alleviate the aforesaid drawbacks of the prior art.

According to one aspect of this invention, there is provided amethod for preparing a semiconductor UNCD film. The method includes doping an UNCD film with an ion source at a dose not less than 10¹⁵ ions/cm² through ion implantation techniques, and annealing the doped UNCD film in an atmosphere including hydrogen gas and nitrogen gas at a temperature ranging from 600 to 800° C. for at least one hour.

According to another aspect of this invention, there is provided a semiconductor UNCD film prepared from the method of this invention. Particularly, the ion source is a nitrogen-containing gas and the UNCD film has a nitrogen-doping level ranging from 0.4×10²⁰ to 4×10²¹ ions/cm³ for a thickness range of from 100 nm to 250 nm.

### BRIEF DESCRIPTION OF THE DRAWINGS

Other features and advantages of the present invention will become apparent in the following detailed description of the preferred embodiments of this invention, with reference to the accompanying drawings, in which:

FIG. 1 shows secondary ion mass spectroscopy (SIMS) data for illustrating a relation curve of the percentage of N₂ gas added to plasma to total nitrogen content in N-doped UNCD film made by prior art PECVD;

FIG. 2 shows a flow chart to illustrate the preferred embodiment of a method for preparing a semiconductor UNCD film according to this invention;

FIG. 3 shows a current density vs. field plot for illustrating EFE properties of the N-doped UNCD films of examples and comparative examples doped with different doses of nitrogen ions before the annealing process;

FIG. 4 shows a current density vs. field plot for illustrating EFE properties of the N-doped UNCD film of examples and comparative examples doped with different doses of nitrogen ions after the annealing process;

FIG. 5 shows a Fowler-Nordheim plot (F-N plot) derived from calculation of data of the plot of FIG. 3;

FIG. 6 shows a Fowler-Nordheim plot (F-N plot) derived from calculation of data of the plot of FIG. 4;

FIG. 7 illustrates turn-on field vs. nitrogen ion doses plot for illustrating the variation of the turn-on field with different implanated nitrogen doses;

FIG. 8 illustrates current density vs. nitrogen ion doses plot for illustrating the variation in the current density with different implanated nitrogen doses at a constant applied field;

FIG. 9 shows Raman spectra of the pristine UNCD film;

FIG. 10 shows Raman spectra of the N-doped UNCD film of an example doped with 10¹² ions/cm² of nitrogen ions before the annealing process;

FIG. 11 shows Raman spectra of the N-doped UNCD film of the example doped with 10¹² ions/cm² of nitrogen ions after the annealing process;

FIG. 12 shows near edge X-ray absorption fine structure (NEXAFS) spectra for illustrating absorption intensity of the pristine UNCD film and the N-doped UNCD films of the examples doped with different doses of nitrogen ions before or after the annealing process as a function of photon energy;

FIG. 13 shows Raman spectra of the semiconductor UNCD film of the example doped with 10¹⁵ ions/cm² of nitrogen ions before the annealing process; and

FIG. 14 shows Raman spectra of the semiconductor UNCD film of the example doped with 10¹⁵ ions/cm² of nitrogen ions after the annealing process.

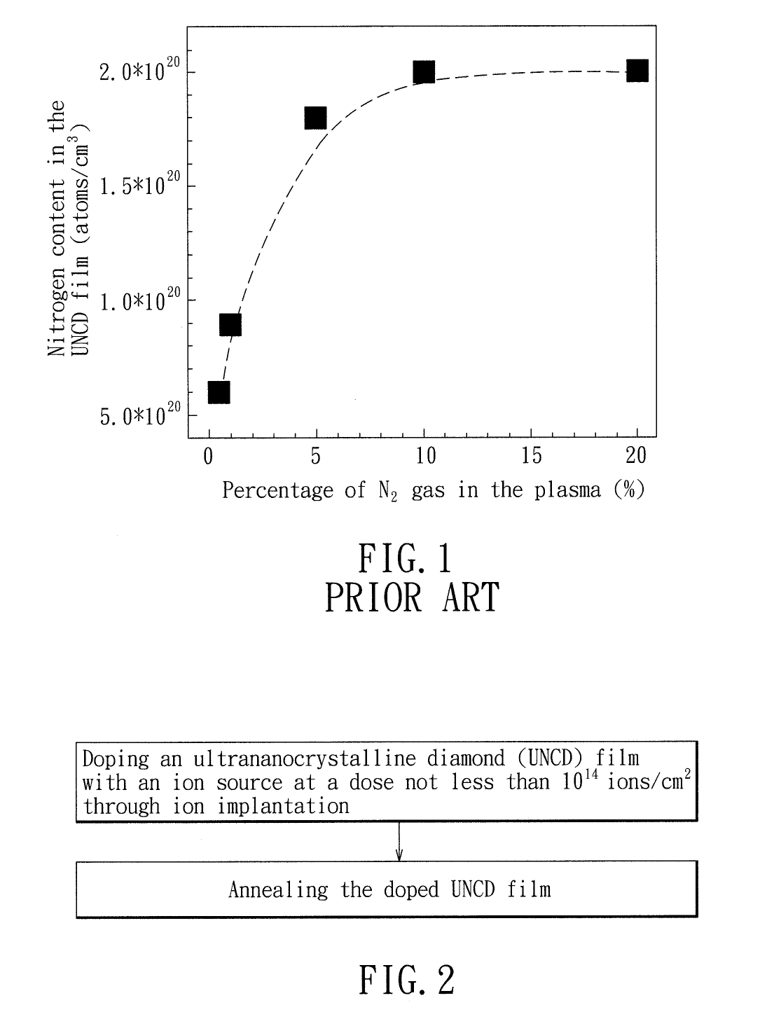

### DETAILED DESCRIPTION OF THE PREFERRED EMBODIMENTS

Referring to FIG. 2, the preferred embodiment of a method for preparing a semiconductor UNCD film according to the present invention includes doping an UNCD film with an ion source through ion implantation, and annealing the doped UNCD film.

The improved EFE properties of the semiconductor UNCD film prepared by the method of this invention can be evaluated by Raman spectroscopy analysis and near edge X-ray absorption fine structure (NEXAFS) spectroscopy analysis. This will be explained in more detail hereinafter.

The UNCD film used in the preferred embodiment of the method for preparing a semiconductor UNCD film according to this invention may be prepared by pre-seeding UNCD nuclei on an n-type silicon (Si) substrate, followed by growing an UNCD film on the Si substrate through MPECVD techniques. Since formation of the UNCD film on the Si substrate is not an essential feature of this invention, details thereof are omitted herein.

Preferably, the UNCD film formed on the Si substrate has a grain size ranging from 5 to 30 nm and a thickness ranging from 50 nm to 1000 nm.

In one preferred embodiment, the ion source used in the doping of the UNCD film is at a dose not less than 10¹⁴ ions/cm². Preferably, the ion source is a nitrogen (N) ion source produced from a N-containing gas. Non-limiting examples of the nitrogen-containing gas include nitrogen gas and ammonia gas. Preferably, the dose of the N ion source produced is not less than 10¹⁵ ions/cm². More preferably, the dose of the N ion source ranges from 10¹⁵ ions/cm² to 10¹⁶ ions/cm².

In another preferred embodiment, the doping of the UNCD film with the N ion source is conducted at room temperature. Preferably, the doping of the UNCD film with the N ion source is conducted at a pressure not less than 10⁻⁶ torr, and the ion source has a kinetic energy ranging from 50 to 300 KeV. More preferably, the ion source has a kinetic energy not less than 100 KeV.

In one preferred embodiment, the annealing of the doped UNCD film is conducted in an atmosphere including hydrogen gas and nitrogen gas. Preferably, the hydrogen gas and the nitrogen gas are in the ratio of 1:9. Preferably, the annealing of the doped UNCD film is conducted at a temperature ranging from 600 to 800° C. More preferably, the annealing of the doped UNCD film is conducted for at least one hour.

### EXAMPLES

The UNCD films were grown on an n-type Si substrate by MPECVD process (IPLAS-Cyrannus). Prior to the growth of the UNCD films, the substrate was preseeded by carburization in hydrocarbon plasma containing 1% CH₄/Ar at 1200 W and at 150 Torr for 25 min followed by ultrasonication in nanodiamond powder containing methanol for 30 min. The deposition of UNCD films on the Si substrate was carried out in a CH₄/Ar plasma with the same parameters as those of the hydrocarbon plasma pretreatment. The growth process of the UNCD films was carried out at a temperature lower than 465° C. for 180 min to reach a thickness of 250 nm.

Then, the UNCD films were implanted with nitrogen ions to a dose of 10¹¹, 10¹², and 10¹³ (comparative examples-relatively low N-doping levels), and 10¹⁴, 10¹⁵, and 10¹⁶ ions/cm² (examples of this invention—relatively high N-doping levels) at room temperature and at 5×10⁻⁶ torr with nitrogen ion source of 100 keV kinetic energy (HVEE 500 KV-Implantor).

After implantation of the UNCD films with difference nitrogen ion doses, the implanted UNCD films were annealed at 600° C. in an atmosphere including hydrogen gas and nitrogen gas in the ratio of 1:9 for less than one hour so as to obtain stabilized semiconductor UNCD films.

EFE properties were investigated for samples of the pristine UNCD films before the ion implantation process and samples of the UNCD films implanted with different N ion doses before and after the annealing process using an,electrometer (Keithley 237), Raman spectroscopy and near edge X-ray absorption fine structure (NEXAFS) spectroscopy analyses.

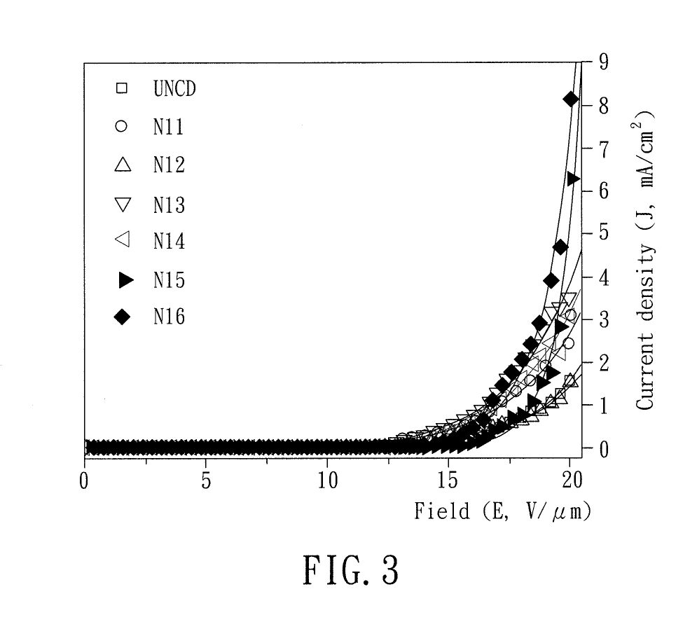

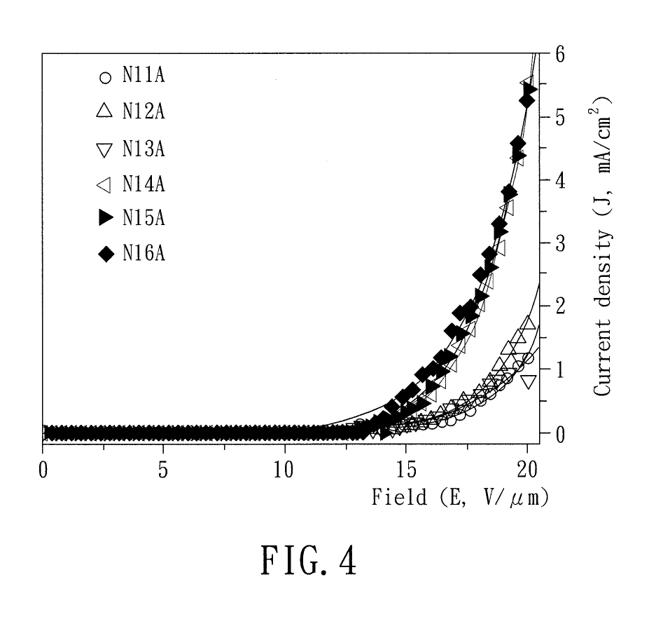

In FIG. 3, UNCD stands for the pristine UNCD films, and N11, N12, N13, N14, N15, and N16 respectively stand for the UNCD films doped with nitrogen ions at doses of 10¹¹, 10¹², 10¹³, 10¹⁴, 10¹⁵, and 10¹⁶ ions/cm² before the annealing process. In FIG. 4, N11A, N12A, N13A, N14A, N15A, and N16A respectively stand for the UNCD films doped with nitrogen ions at doses of 10¹¹, 10¹², 10¹³, 10¹⁴, 10¹⁵, and 10¹⁶ ions/cm² after the annealing process.

FIGS. 3 and 4 show current density vs. field plots for illustrating EFE properties of the semiconductor UNCD films of the examples doped with different doses of nitrogen ions before and after the annealing process, respectively. Referring to FIG. 3, the current density of the N-doped UNCD films of either the comparative examples or examples at a constant applied field of 20 V/μm increase with the increase of the dose of the nitrogen ions. Meanwhile, referring to FIG. 4, after the annealing process, only the N-doped UNCD films of the examples implanted with the relatively high nitrogen-doping levels are able to maintain a relatively high current density. In particular, the current density of the pristine UNCD film at the constant applied field of 20 V/μm is about 1.54 mA/cm² (see FIG. 3), whereas the current density of the semiconductor UNCD film of the examples implanted with the relatively high nitrogen-doping level (10¹⁵ ions/cm²) after the annealing process is increased to 6.3 mA/cm².

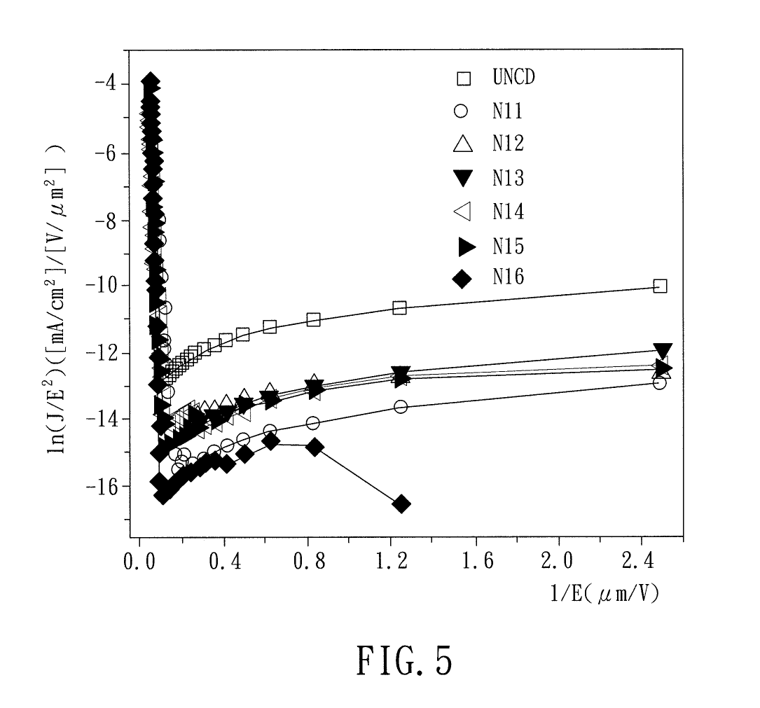

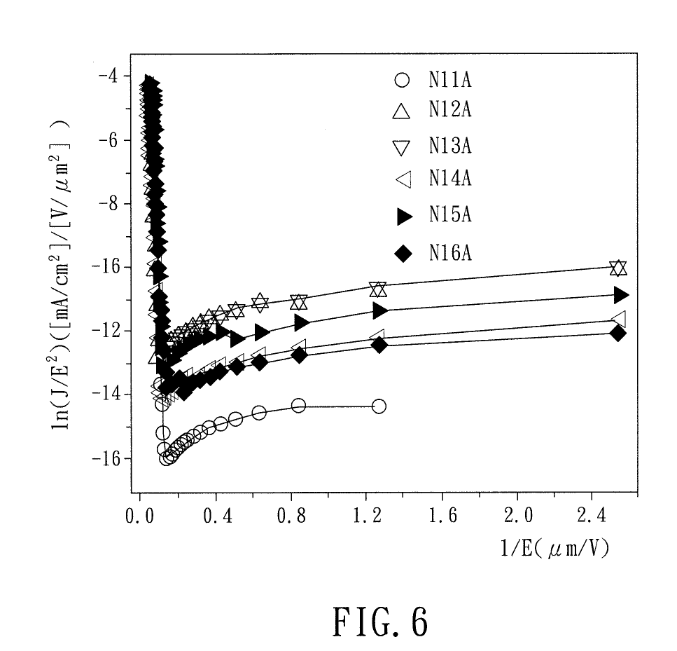

FIGS. 5 and 6 show Fowler-Nordheim plots (F-N plots) derived from calculation of data of the plots of FIGS. 3 and 4, respectively. The axis of abscissa represents the reciprocal (1/E) of the field (E), and the axis of ordinate represents the natural logarithm of the quotient (J/E²) of current density (J) divided by field squared (E²). The turn-on field is the reciprocal of the lowest value of the F-N plots.

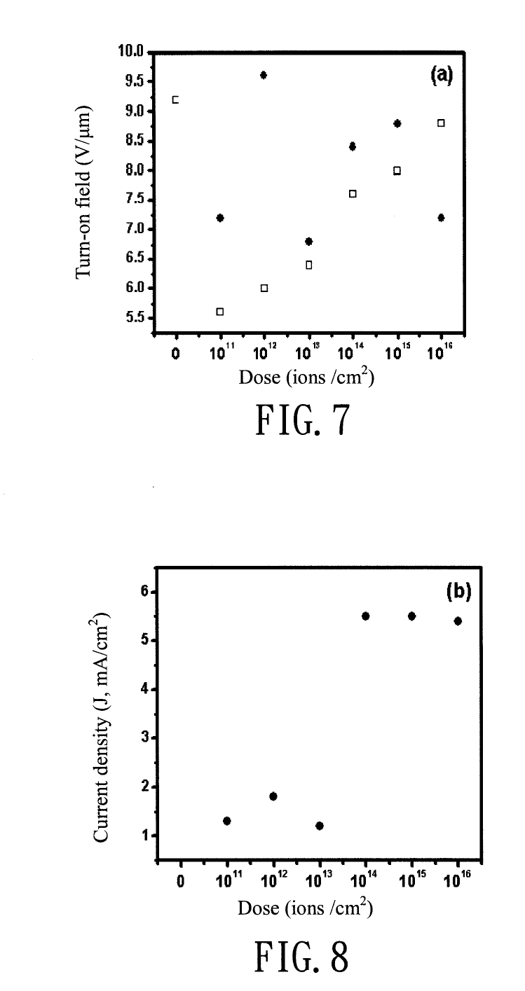

FIG. 7 illustrates turn-on field (V/μm) vs. N ion doses (ions/cm²) plot for illustrating the variation of the turn-on field with different N ion doses. The data obtained before the annealing process are expressed by the symbol “open square,” while the data obtained after the annealing process are expressed by the symbol “closed circle.” As shown in FIG. 7, the turn-on field of the pristine UNCD film is calculated to 9.2 V/μm; the turn-on fields of the N-doped UNCD film of the comparative examples having the relatively low N-doping level (10¹² ions/cm²) before and after the annealing process are calculated to be 6.0 V/μm and 9.6 V/μm, respectively; and the turn-on fields of the semiconductor UNCD film of the example implanted with the relatively high nitrogen-doping level (10¹⁵ ions/cm²) before and after the annealing process are calculated to be 8.0 V/μm and 8.8 V/em, respectively. According to FIG. 7, before the annealing process, the turn-on field is decreased with the increase of the dose of nitrogen ions when the N ion dose is 10¹¹ ions/cm², whereas the turn-on field is increased with the increase of the dose of nitrogen ions when the N ion dose is more than 10¹¹ ions/cm². After the annealing process, the turn-on fields are increased compared to those before the annealing process, except for the N ion dose of 10¹⁶ ions/cm². The reason for the results of FIGS. 7 will be explained hereinafter.

FIG. 8 shows a plot of current density (mA/cm², J) vs. N ion doses (ions/cm²) at an applied field of 20 V/μm. It indicates that the post annealing reverted the EFE current density back to a level the same as that of the pristine UNCD for the low dose (less than 10¹³ ions/cm²) of N ion-implanted UNCD films. Nevertheless, the high emission current densities for the high dose (10¹⁴ ions/cm² or above) of N-ion implanted UNCD films are retained.

In addition, according to this invention, the doping of the UNCD film with the nitrogen ions is conducted through the ion implantation techniques, and the dose of nitrogen ions can be relatively precisely controlled. Hence, the nitrogen content in the doped UNCD film can be calculated and quantified. For example, when the UNCD film is 250 nm thick, if the dose of nitrogen ions is 10¹⁵ ions/cm², the nitrogen content in the doped UNCD film is calculated to be 0.4×10²⁰ ions/cm³, and if the dose of nitrogen ions is 10¹⁶ ions/cm², the nitrogen content in the doped UNCD film is increased to 4.0×10²⁰ ions/cm³ upon calculation. On the other hand, when the UNCD film is 100 nm thick, if the dose of nitrogen ions is 10¹⁵ ions/cm², the nitrogen content in the doped UNCD film is calculated to be 1.0×10²⁰ ions/cm², and if the dose of nitrogen ions is 10¹⁶ ions/cm², the nitrogen content in the doped UNCD film is increased to 4.0×10²¹ ions/cm³ upon calculation. Based on the above results, the N ion dose should be higher than a threshold value in order to enhance field emission properties. Preferably, the threshold value is not less than 10¹⁴ ions/cm². More preferably, the threshold value ranges from 10¹⁵ ions/cm² to 10¹⁶ ions/cm², in consideration of the relatively long process time required for the relatively high dose of the nitrogen ions.

Variation of the structure of the doped UNCD film with different N ion doses will be illustrated by means of the following measurements.

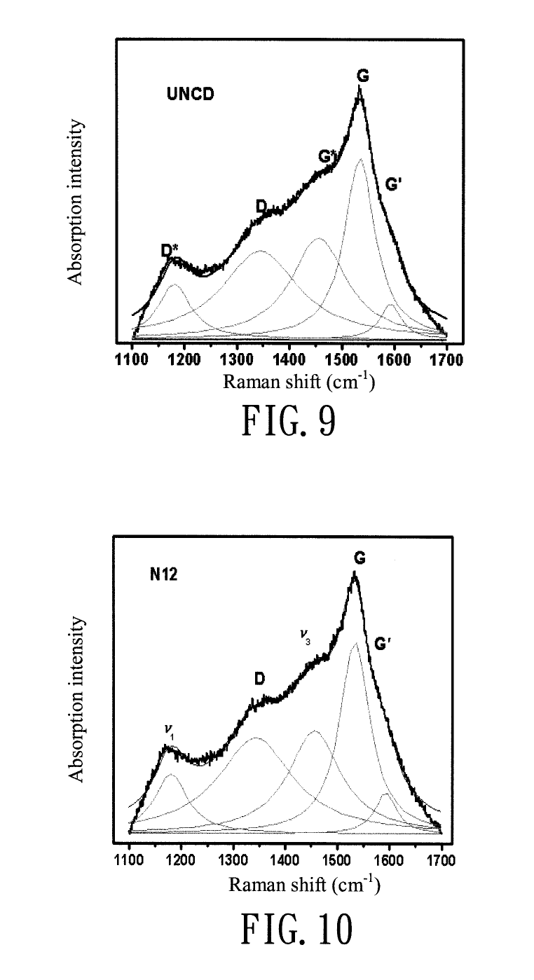

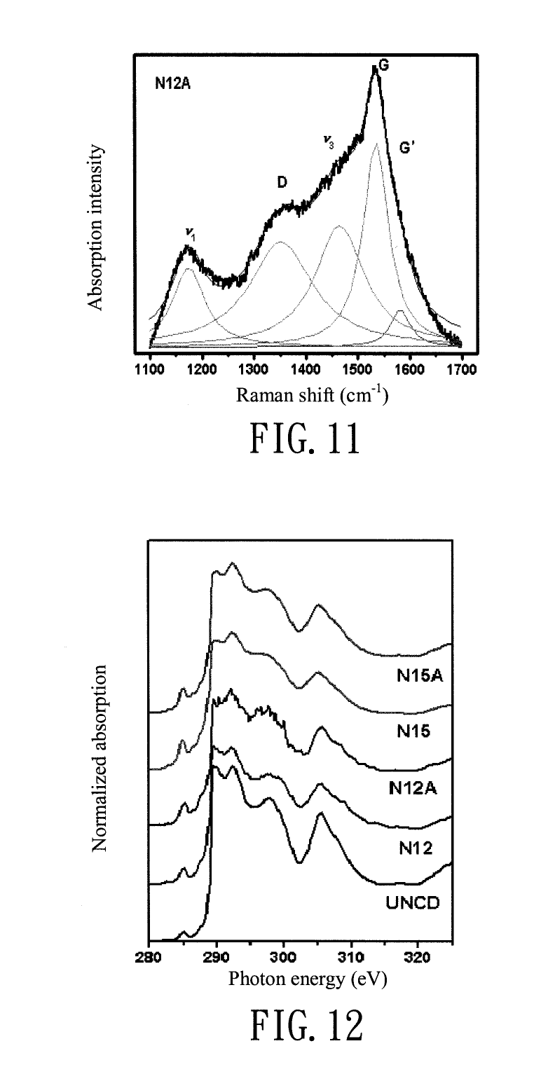

FIG. 9 shows Raman spectra of the pristine UNCD film; FIG. 10 shows Raman spectra of the N-doped UNCD film of the comparative example doped with 10¹²ions/cm² of nitrogen ions before the annealing process; and FIG. 11 shows Raman spectra of the N-doped UNCD film of the comparative example doped with 10¹²ions/cm² of nitrogen ions after the annealing process. In FIG. 9, a broad peak observed at about 1350 cm⁻¹ is assigned as a D band of UNCD, which resulted from defects of the UNCD grains and defects produced during growth of the UNCD grains. The peaks at about 1170 cm-¹ and 1450 cm-¹ (absorbance values v, and V₃) are affirmed to trans-polyacetylene present on grain boundaries of the UNCD film. The peak at 1532 cm⁻¹ is assigned as a G band of UNCD. Generally, G-band of UNCD appears at about 1500 cm⁻¹ to 1600 cm⁻¹. The shoulder peak appearing at 1600 cm^{—1} is assigned as a G′-band and resulted from absorbance of sp2 -bonding of the UNCD grains. Comparing FIGS. 10 and 11 with FIG. 9, since the Raman spectra of FIGS. 10 and 11 (the UNCD film doped with 10¹² ions/cm² of nitrogen ions) are similar to that of FIG. 9 (the pristine UNCD film), it is apparent that the structure of the UNCD film with the relatively low nitrogen-doping level tends to self-heal to the original state of the pristine UNCD film.

FIG. 12 shows NEXAFS spectra for illustrating a relation curve of absorption intensity of the pristine UNCD film and the N-doped UNCD films doped with different dose of nitrogen ions (10¹² ions/cm² and 10¹⁵ ions/cm²) before or after the annealing process to photon energy. The sharp rise in absorption near 289.7 eV and a deep valley near 302.5 eV clearly indicate the sp3 -bond absorption of the typical UNCD grains. As for the UNCD films doped with different doses of nitrogen ions either before or after the annealing process, the peaks of absorption near 285.0 eV (assigned as a π* bond) of the doped UNCD films are higher than that of the pristine UNCD. This indicates that the doped UNCD films have more graphitic phases than that of the pristine UNCD. However, for the whole semiconductor UNCD film, after implantation of nitrogen ions, the main structure of the UNCD can be maintained since sp³-bonds of the UNCD are not destroyed during implantation of nitrogen ions, and only a part of the microstructure of the UNCD is changed.

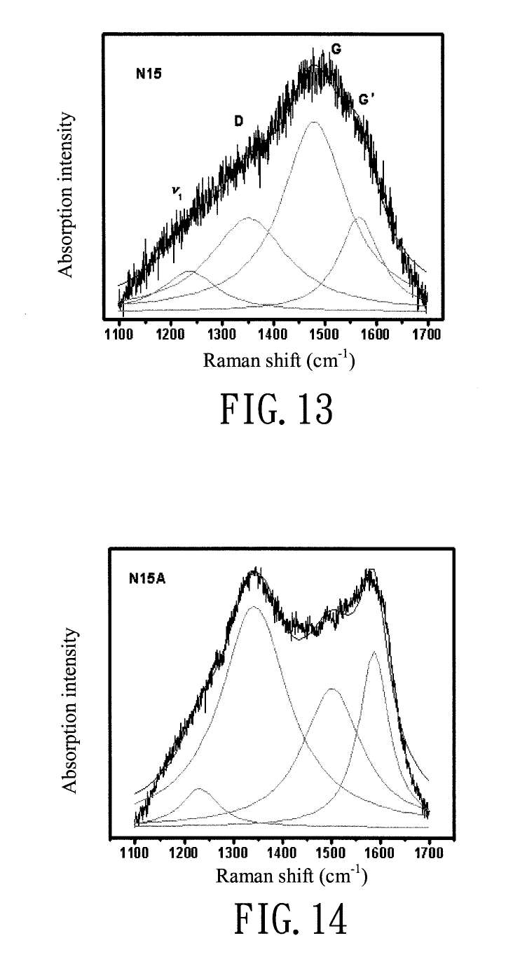

FIGS. 13 and 14 show Raman spectra of the semiconductor UNCD filmof the example dopedwithl 10¹⁵ ions/cm² of nitrogen ions before and after the annealing process, respectively. It is apparent that D- or G-bands of the typical UNCD disappear due to surface amorphization of the semiconductor UNCD film caused by the relatively high nitrogen-doping level (10¹⁵ ions/cm²). Besides, after the annealing process, the amorphous surface of the semiconductor UNCD film is unable to heal but is converted to a relatively stable nano-graphitic phase as indicated by the peak at about 1580 cm⁻¹.

Defects formed through surface amorphization of the UNCD films doped with different doses of nitrogen ions and post-implantation annealing processes are briefly summarized in Table 1.

TABLE 1
Effects of nitrogen-ion implantation and
post-implantation annealing process on the formation of
defects in UNCD.

| Dose of N | | | Defects in the |
|---|---|---|---|
| ions | | Post-implantation | semiconductor |
| (ions/cm²) | As implantation | annealing | UNCD film |
| 10¹¹ to 10¹² | H⁻ removal | H⁻ intake | Lightly doped N |
| 10¹³ | Displaced carbon | Healed | Lightly doped N |
| 10¹⁴ | Defect complex | Stabilized to | Carbon clusters + |
| | (carbon | carbon clusters | doped N + grain |
| | clusters, | | boundary N |
| | vacancy dimmer, | | |
| | trimer, etc.) | | |
| 10¹⁵ | Defect complex | Carbon clusters + | Carbon clusters + |
| | (carbon clusters | nanographites | nanographites + |
| | with a small | (small | doped N + grain |
| | amorphous | concentration) | boundary N |
| | portion) | | |
| 10¹⁶ | Amorphous (large | Nanographites | nanographites + |
| | concentration) | (large | doped N + grain |
| | | concentration) | boundary N |

According to Table 1, when the N-doped UNCD film is doped with the dose of the nitrogen ions less than 10¹⁴ ions/cm², the surface defects can be healed by the annealing process back to the original state of the pristine UNCD. Hence, the nitrogen content that can be implanted in the UNCD film is relatively low, and the N ions implanted in the UNCD film are located in the UNCD grains. On the other hand, when the N-doped UNCD film is doped with the dose of the nitrogen ions not less than 10¹⁴ ions/cm², the surface of the UNCD film starts to produce different amorphous levels, and the surface defects thus formed are unable to be healed by the annealing process and brought back to the pristine UNCD. The doped N ions in the UNCD grains are transferred to the UNCD grain boundaries. The presence of the grain boundary doping of N ions can enhance the EFE properties.

The kinetics of defect formation due to ion implantation can account for the modification of the EFE behavior of UNCD films. Interband electronic states in diamond material are formed due to the presence of small defects, which facilitate the jump of electrons from valence band to conduction band and lower the turn-on field for EFE process. Such a mechanism applies when the defects are small in size, which occurs for the comparative examples with low doses (i.e., N11-N13, open squares, in FIG. 7). After annealing, the small defects are either annihilated or collapsed, thereby eliminating the intermediate energy levels. The turn-on field is thus brought back to the original high level (closed circles in FIG. 7). However, for the example (N16), ion implantation/post annealing induces the formation of nanographite, which facilitates the electron transport and leads to a further lowering of the turn-on field, but to a much lesser extent.

The properties of the pristine UNCD and the N-doped UNCD films doped with different doses of nitrogen ions are briefly summarized in Table 2.

TABLE 2
Properties of the pristine UNCD and the N-doped
UNCD films doped with different doses of nitrogen ions.

| | Kinetic | | | | | Post-implantation | | |
|---|---|---|---|---|---|---|---|---|
| | energy | Dose of N | As implantation | | | annealing | | |
| UNCD | of N ions | ions | E₀ | J | | E₀ | J | |
| film | (KeV) | (ions/cm²) | (V/μm) | (mA/cm²) | Φ_{e (eV)} | (V/μm) | (mA/cm²) | Φ_{e (eV)} |
| UNCD | — | — | 9.2 | 1.54 | 0.0228 | — | — | — |
| N12 | 100 | 1 × 10¹² | 6.0 | 1.54 | 0.0178 | 9.6 | 1.71 | 0.0231 |
| N15 | 100 | 1 × 10¹⁵ | 8.0 | 6.3 | 0.0229 | 8.8 | 5.42 | 0.0236 |

Note:
UNCD: the pristine UNCD
N12: the N-doped UNCD film doped with 1 × 10¹² ions/cm² of N ions
N15: the N-doped UNCD film doped with 1 × 10¹⁵ ions/cm² of N ions
E₀: turn-on field
J: current density
Φₑ: effective workfunction

According to the data shown in Table 2, before the annealing process, the relatively low N-doping level results in change of the turn-on field (E₀) of the N-doped UNCD film but has no effect on the current density (J) The reason is that the relatively low N-doping level results in formation of point defects and such defects induce a different energy level distribution. Hence, electrons are allowed to jump from the valence band to the conducting band through these energy levels. Consequently, the turn-on field is decreased. However, after the annealing process, the doped UNCD film tends to recover to the original state equal to the pristine UNCD film before doping. On the other hand, before the annealing process, the relatively high N-doping level results in formation of a defect complex, and second phases, such as amorphous phase and nano-graphitic phase. The defect complex and the second phase before and after the annealing process do not induce any different energy level distribution. Hence, the turn-on field of the N-doped film is not greatly changed after the annealing process. However, the existence of N ions in the grain boundaries greatly enhances the EFE properties of the N-doped UNCD film (the semiconductor UNCD film of this invention).

By virtue of the method of this invention, the semiconductor UNCD film thus formed is suitable for field emitters in a planar surface form in contrast to the traditional conical emitters. Hence, the complexity and production cost of the method of this invention are lower than those of the conventional FEA techniques. In addition, in the method of this invention, the doping of the UNCD film with the nitrogen ions is conducted through the ion implantation techniques, and the dose of nitrogen ions can be relatively precisely controlled. Hence, a semiconductor UNCD film with a relatively high N-doping level can be obtained. Such semiconductor UNCD film has greatly improved EFE properties, in addition to chemical inertness and excellent mechanical strength.

While the present invention has been described in connection with what are considered the most practical and preferred embodiments, it is understood that this invention is not limited to the disclosed embodiments but is intended to cover various arrangements included within the spirit and scope of the broadest interpretation and equivalent arrangements.

What is claimed is:

1. A method for preparing a semiconductor ultrananocrystalline diamond (UNCD) film, comprising:
doping an ultrananocrystalline diamond (UNCD) film with an ion source at a dose not less than 10¹⁴ions/cm² through ion implantation; and
annealing the doped UNCD film.

2. The method of claim 1, wherein the UNCD filmhas a grain size ranging from 5 to 30 nm and a thickness ranging from 50 nm to 1000 nm.

3. The method of claim 1, wherein the ion source is a nitrogen (N) ion source produced from a nitrogen-containing gas.

4. The method of claim 3, wherein the nitrogen-containing gas is one of nitrogen gas and ammonia gas.

5. The method of claim 3, wherein the dose of the N ion source is not less than 10¹⁵ ions/cm¹².

6. The method of claim 5, wherein the dose of the N ion source ranges from 10¹⁵ ions/cm² to 10¹⁶ ions/cm².

7. The method of claim 3, wherein the doping of the N ion source is conducted at room temperature.

8. The method of claim 3, wherein the doping of the UNCD film is conducted at a pressure not less than 10⁻⁶ torr, the ion source having a kinetic energy ranging from 50 to 300 KeV.

9. The method of claim 3, wherein the annealing is conducted in an atmosphere including hydrogen gas and nitrogen gas.

10. The method of claim 9, wherein the hydrogen gas and the nitrogen gas are in the ratio of 1:9.

11. The method of claim 9, wherein the annealing is conducted at a temperature ranging from 600 to 800° C.

12. The method of claim 10, wherein the annealing is conducted for at least one hour.

13. A semiconductor ultrananocrystalline diamond (UNCD) film prepared from the method according to claim 3, wherein said film has a nitrogen-doping level ranging from 0.4×10²⁰ to 4×10 ions/cm³ for a thickness range of from 100 nm to 250 nm.
